(19) United States
(12) Patent Application Publication
(10) Pub. No.: US 2026/0173355 A1
(43) Pub. Date: Jun. 18, 2026

(54) SUBSTRATE ISOLATION FOR STACKED MEMORY BIT LINE AND CAPACITOR

(71) Applicant: Samsung Electronics Co., Ltd., Suwon-si (KR)

(72) Inventors: Sanyum CHANNA, San Jose, CA (US); Dongwan KIM, San Jose, CA (US); Young Doo JEONG, Campbell, CA (US); Mohd Kamran AKHTAR, San Jose, CA (US); Dohyung KIM, San Jose, CA (US); Wangee KIM, Dublin, CA (US)

(21) Appl. No.: 19/310,894

(22) Filed: Aug. 26, 2025

Related U.S. Application Data
(60) Provisional application No. 63/735,882, filed on Dec. 18, 2024.

(51) Int. Cl. H10B 12/00; H10D 1/68

(52) U.S. Cl. CPC H10B 12/482; H10D 1/714; H10B 12/03

(57) ABSTRACT

Provided are systems, methods, and apparatuses for substrate isolation for a stacked memory bit line and/or capacitor. In one or more examples, the systems, devices, and methods include forming an open trench between layers of a semiconductor; performing a thinning process that includes forming thinned layers of the semiconductor the thinning process and forming a gap layer by removing a bottom layer of the semiconductor; filling the open trench with a dielectric that covers exposed surfaces of the open trench, including the thinned layers of the semiconductor; performing a removal process that includes removing an upper portion of the dielectric, the dielectric remaining in the gap layer and a bottom portion of the open trench; and filling a portion of the open trench above the dielectric with a conductive material.

### CROSS-REFERENCE TO RELATED APPLICATIONS

This application claims the benefit of U.S. Provisional Patent Application Ser. No. 63/735,882, filed Dec. 18, 2024, which is incorporated by reference herein for all purposes.

### TECHNICAL FIELD

The disclosure relates generally to memory systems. In particular, the subject matter relates to systems, methods, and devices for forming electrical isolation structures between the substrate layer and components of a stacked memory (e.g., bitlines and/or capacitors).

### BACKGROUND

The present background section is intended to provide context only, and the disclosure of any concept in this section does not constitute an admission that said concept is prior art.

Random-access memory (RAM) is a type of computer memory that allows data to be read and changed in any order, crucial for a computer's central processing unit (CPU) to quickly access working data and machine code. Dynamic RAM (DRAM), a type of RAM, is widely used due to its efficiency and high capacity, storing each bit of data in a capacitor accessible via a transistor, where the capacitor may be constantly refreshed to maintain a data charge. Stacked memory based on DRAM, including 3D-DRAM, vertically stacked DRAM (VS-DRAM), and hybrid memory cube (HMC), addresses memory bandwidth limitations in multi-core processors by vertically stacking multiple DRAM dies within the same package, leading to significantly higher bandwidth and potentially lower power consumption compared to conventional DRAM modules. However, stacked DRAM presents challenges related to thermal management and increased manufacturing complexity.

### SUMMARY

In various embodiments, the systems and methods described herein include systems, methods, and apparatuses associated with substrate isolation for a stacked memory bit line and/or capacitor. In some aspects, the techniques described herein relate to a memory device including: a substrate layer; layers of a semiconductor formed horizontally over the substrate layer; a gap layer formed horizontally between the substrate layer and a first layer of the layers of the semiconductor; an open trench vertically bifurcating the layers of the semiconductor; a dielectric that fills the gap layer and a bottom portion of the open trench based on a filling process; and a conductor that fills an upper portion of the open trench.

In some aspects, the techniques described herein relate to a memory device, further including: a second open trench that vertically bifurcates second layers of the semiconductor; a second gap layer and a bottom portion of the second open trench filled with the dielectric; and a second conductor that fills an upper portion of the second open trench.

In some aspects, the techniques described herein relate to a memory device, wherein: the conductor of the open trench forms a local bitline, and the second conductor of the second open trench forms a conductive element of a capacitor.

In some aspects, the techniques described herein relate to a memory device, wherein a thinning process includes: thinning the layers of the semiconductor, and thinning the second layers of the semiconductor.

In some aspects, the techniques described herein relate to a memory device, wherein the filling process includes: filling the gap layer and bottom portion of the open trench, the dielectric being allowed to grow to fill in a portion of the gap layer and the bottom portion of the open trench, and filling the second gap layer and bottom portion of the second open trench, the dielectric being allowed to grow to fill in a portion of the second gap layer and the bottom portion of the second open trench.

In some aspects, the techniques described herein relate to a memory device, wherein: a first layer of a second semiconductor is formed on the substrate; a first layer of the semiconductor is formed on the first layer of the second semiconductor, the bottom layer of the semiconductor including the first layer of the semiconductor; a second layer of the second semiconductor is formed on the first layer of the semiconductor; and a second layer of the semiconductor is formed on the second layer of the second semiconductor.

In some aspects, the techniques described herein relate to a memory device, wherein: the first layer of the second semiconductor is formed on the substrate with a first thickness between 5 and 20 nanometers; the first layer of the semiconductor is formed on the first layer of the second semiconductor with a second thickness between 10 and 55 nanometers; and the second layer of the semiconductor is formed on the second layer of the second semiconductor with a third thickness between 30 and 100 nanometers.

In some aspects, the techniques described herein relate to a memory device, wherein: the semiconductor includes silicon, and the second semiconductor includes silicon germanium.

In some aspects, the techniques described herein relate to a memory device, wherein the filling process is based on area-selective deposition.

In some aspects, the techniques described herein relate to a memory device, wherein the filling process is based on flowable chemical vapor deposition.

In some aspects, the techniques described herein relate to a method including: forming an open trench between layers of a semiconductor; performing a thinning process that includes forming thinned layers of the semiconductor the thinning process and forming a gap layer by removing a bottom layer of the semiconductor; filling the open trench with a dielectric that covers exposed surfaces of the open trench, including the thinned layers of the semiconductor; performing a removal process that includes removing an upper portion of the dielectric, the dielectric remaining in the gap layer and a bottom portion of the open trench; and filling a portion of the open trench above the dielectric with a conductive material.

In some aspects, the techniques described herein relate to a method, further including: forming a second open trench between second layers of the semiconductor; filling a second gap layer and a bottom portion of the second open trench with the dielectric; and filling an upper portion of the second open trench with a second conductor.

In some aspects, the techniques described herein relate to a method, wherein: the conductor of the open trench forms a local bitline, and the second conductor of the second open trench forms a conductive element of a capacitor.

In some aspects, the techniques described herein relate to a method, wherein the thinning process: thins the layers of the semiconductor, and thins the second layers of the semiconductor.

In some aspects, the techniques described herein relate to a method, wherein the filling process: fills the gap layer and bottom portion of the open trench, the dielectric being allowed to grow to fill in a portion of the gap layer and the bottom portion of the open trench, and fills the second gap layer and bottom portion of the second open trench, the dielectric being allowed to grow to fill in a portion of the second gap layer and the bottom portion of the second open trench.

In some aspects, the techniques described herein relate to a method, wherein the filling process is based on area-selective deposition.

In some aspects, the techniques described herein relate to a method, wherein the filling process is based on flowable chemical vapor deposition.

In some aspects, the techniques described herein relate to a method, further including: forming a liner material over exposed surfaces of the open trench, including the thinned layers of the semiconductor, the liner material including a non-growth material that inhibits growth of the dielectric.

In some aspects, the techniques described herein relate to a method, wherein forming the layers of the semiconductor include removing layers of a second semiconductor interleaved between layers of the semiconductor, the layers of the semiconductor including multiple layers of a first thickness and the bottom layer of the semiconductor having a second thickness less than the first thickness.

In some aspects, the techniques described herein relate to a fabrication device for fabricating memory devices, the fabrication device being configured to: form an open trench between layers of a semiconductor; perform a thinning process that includes forming thinned layers of the semiconductor the thinning process and forming a gap layer by removing a bottom layer of the semiconductor; fill the open trench with a dielectric that covers exposed surfaces of the open trench, including the thinned layers of the semiconductor; perform a removal process that includes removing an upper portion of the dielectric, the dielectric remaining in the gap layer and a bottom portion of the open trench; and fill a portion of the open trench above the dielectric with a conductive material.

A computer-readable medium is disclosed. The computer-readable medium can store instructions that, when executed by a computer, cause the computer to perform substantially the same or similar operations as described herein are further disclosed. Similarly, non-transitory computer-readable media, devices, and systems for performing substantially the same or similar operations as described herein are further disclosed.

The systems and methods described herein include multiple advantages and benefits. For example, processes described herein for the formation of substrate isolation may be insensitive to trench depth variation. Similarly, the processes described herein may be insensitive to relatively deep lateral recess (e.g., resulting in minimal isolation damage). The processes described herein may be integrated with multiple schemes (e.g., multiple depositions schemes). In some embodiments, substrate isolation can be created in one process for a local bit line (LBL) and another process for a capacitor of the stacked memory device. In some cases, one process may be used to provide substrate isolation for LBLs and capacitors simultaneously or concurrently (e.g., at least a portion of an LBL process overlaps with a capacitor process). In some embodiments, the formation of the substrate isolation may be insensitive to deep oxide/nitride lateral recesses. In some embodiments, the formation of the substrate isolation may be insensitive to relatively large trench height variation. In some embodiments, the formation of the substrate isolation may be integrated into several schemes (e.g., wordline (WL), LBL, and/or capacitor schemes). In some embodiments, the formation of the substrate isolation may be based on a relatively small number of additional steps (e.g., 1-3 flowable chemical vapor deposition (FCVD) steps; 3-5 area-selective deposition (ASD) steps). In some embodiments, ASD may utilize a thickness range on relatively few deposition steps. In some embodiments, FCVD may use a relatively high number of dummy tiers.

### BRIEF DESCRIPTION OF THE DRAWINGS

The above-mentioned aspects and other aspects of the present systems and methods will be better understood when the present application is read in view of the following figures in which like numbers indicate similar or identical elements. Further, the drawings provided herein are for purpose of illustrating certain embodiments only; other embodiments, which may not be explicitly illustrated, are not excluded from the scope of this disclosure.

These and other features and advantages of the present disclosure will be appreciated and understood with reference to the specification, claims, and appended drawings, wherein:

FIG. 1 illustrates an example structure in accordance with one or more implementations as described herein.

FIG. 2 illustrates an example structure in accordance with one or more implementations as described herein.

FIG. 3 illustrates an example structure in accordance with one or more implementations as described herein.

FIG. 4 illustrates an example structure in accordance with one or more implementations as described herein.

FIG. 5 illustrates an example structure in accordance with one or more implementations as described herein.

FIG. 6 illustrates an example structure in accordance with one or more implementations as described herein.

FIG. 7 illustrates an example structure in accordance with one or more implementations as described herein.

FIG. 8 illustrates an example structure in accordance with one or more implementations as described herein.

FIG. 9 illustrates an example structure in accordance with one or more implementations as described herein.

FIG. 10 depicts a flow diagram illustrating an example method associated with the disclosed systems, in accordance with example implementations described herein.

FIG. 11 illustrates an example system in accordance with one or more implementations as described herein.

While the present systems and methods are susceptible to various modifications and alternative forms, specific embodiments thereof are shown by way of example in the drawings and will herein be described. The drawings may not be to scale. It should be understood, however, that the drawings and detailed description thereto are not intended to limit the present systems and methods to the particular form disclosed, but to the contrary, the intention is to cover all modifications, equivalents, and alternatives falling within the spirit and scope of the present systems and methods as defined by the appended claims.

### DETAILED DESCRIPTION OF VARIOUS EMBODIMENTS

The details of one or more embodiments of the subject matter described herein are set forth in the accompanying drawings and the description below. Other features, aspects, and advantages of the subject matter will become apparent from the description, the drawings, and the claims.

Various embodiments of the present disclosure are described with reference to the accompanying drawings, in which some, but not all embodiments are shown. Indeed, the disclosure may be embodied in many forms and should not be construed as limited to the embodiments set forth herein; rather, these embodiments are provided so that this disclosure will satisfy applicable legal requirements. The term “or” is used herein in both the alternative and conjunctive sense, unless otherwise indicated. The terms “illustrative” and “example” are used to be examples with no indication of quality level. Like numbers refer to like elements throughout. Arrows in each of the figures depict bi-directional data flow and/or bi-directional data flow capabilities. The terms “path,” “pathway” and “route” are used interchangeably herein.

Embodiments of the present disclosure may be implemented in various ways, including as computer program products that comprise articles of manufacture. A computer program product may include a non-transitory computer-readable storage medium storing applications, programs, program components, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media includes all computer-readable media (including volatile and non-volatile media).

In one embodiment, a non-volatile computer-readable storage medium may include a floppy disk, flexible disk, hard disk, solid-state storage (SSS) (for example a solid-state drive (SSD)), solid state card (SSC), solid state module (SSM), enterprise flash drive, magnetic tape, or any other non-transitory magnetic medium, and/or the like. A non-volatile computer-readable storage medium may include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may include read-only memory (ROM), programmable read-only memory (PROM), erasable programmable read-only memory (EPROM), electrically erasable programmable read-only memory (EEPROM), flash memory (for example Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may include conductive-bridging random-access memory (CBRAM), phase-change random-access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random-access memory (FJG RAM), Millipede memory, racetrack memory, and/or the like.

In one embodiment, a volatile computer-readable storage medium may include random-access memory (RAM), dynamic random-access memory (DRAM), static random-access memory (SRAM), fast page mode dynamic random-access memory (FPM DRAM), extended data-out dynamic random-access memory (EDO DRAM), synchronous dynamic random-access memory (SDRAM), double data rate synchronous dynamic random-access memory (DDR SDRAM), double data rate type two synchronous dynamic random-access memory (DDR2 SDRAM), double data rate type three synchronous dynamic random-access memory (DDR3 SDRAM), Rambus dynamic random-access memory (RDRAM), Twin Transistor RAM (TTRAM), Thyristor RAM (T-RAM), Zero-capacitor (Z-RAM), Rambus in-line memory component (RIMM), dual in-line memory component (DIMM), single in-line memory component (SIMM), video random-access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present disclosure may be implemented as methods, apparatus, systems, computing devices, computing entities, and/or the like. As such, embodiments of the present disclosure may take the form of an apparatus, system, computing device, computing entity, and/or the like executing instructions stored on a computer-readable storage medium to perform certain steps or operations. Thus, embodiments of the present disclosure may take the form of a hardware embodiment, a computer program product embodiment, and/or an embodiment that comprises a combination of computer program products and hardware performing certain steps or operations.

Embodiments of the present disclosure are described below with reference to block diagrams and flowchart illustrations. Thus, it should be understood that each block of the block diagrams and flowchart illustrations may be implemented in the form of a computer program product, a hardware embodiment, a combination of hardware and computer program products, and/or apparatus, systems, computing devices, computing entities, and/or the like carrying out instructions, operations, steps, and similar words used interchangeably (for example the executable instructions, instructions for execution, program code, and/or the like) on a computer-readable storage medium for execution. For example, retrieval, loading, and execution of code may be performed sequentially, such that one instruction is retrieved, loaded, and executed at a time. In some examples, retrieval, loading, and/or execution may be performed in parallel, such that multiple instructions are retrieved, loaded, and/or executed together. Thus, such embodiments can produce specifically configured machines performing the steps or operations specified in the block diagrams and flowchart illustrations. Accordingly, the block diagrams and flowchart illustrations support various combinations of embodiments for performing the specified instructions, operations, or steps.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not be necessarily all referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms, and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms, and a plural term may include the corresponding singular form. It is further noted that various figures (including component diagrams) shown and discussed herein are for illustrative purposes only, and are not drawn to scale. Similarly, various waveforms and timing diagrams are shown for illustrative purposes only. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some embodiments and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly referenced parts/modules are the only way to implement some of the embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on chip (SoC), an assembly, and so forth.

The provided description is presented to enable one of ordinary skill in the art to make and use the subject matter disclosed herein and to incorporate it in the context of particular applications. While the following is directed to specific examples, other and further examples may be devised without departing from the basic scope thereof.

Various modifications, as well as a variety of uses in different applications, will be readily apparent to those skilled in the art, and the general principles defined herein may be applied to a wide range of embodiments. Thus, the subject matter disclosed herein is not intended to be limited to the embodiments presented, but is to be accorded the widest scope consistent with the principles and novel features disclosed herein.

In the description provided, numerous specific details are set forth in order to provide a more thorough understanding of the subject matter disclosed herein. It will, however, be apparent to one skilled in the art that the subject matter disclosed herein may be practiced without necessarily being limited to these specific details. In other instances, well-known structures and devices are shown in block diagram form, rather than in detail, in order to avoid obscuring the subject matter disclosed herein.

All the features disclosed in this specification (e.g., any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Various features are described herein with reference to the figures. It should be noted that the figures are only intended to facilitate the description of the features. The various features described are not intended as an exhaustive description of the subject matter disclosed herein or as a limitation on the scope of the subject matter disclosed herein. Additionally, an illustrated example need not have all the aspects or advantages shown. An aspect or an advantage described in conjunction with a particular example is not necessarily limited to that example and can be practiced in any other examples even if not so illustrated, or if not so explicitly described.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the claims herein is not intended to invoke the provisions of 35 U.S.C. 112, Paragraph 6.

It is noted that, if used, the labels left, right, front, back, top, bottom, forward, reverse, clockwise and counterclockwise have been used for convenience purposes only and are not intended to imply any particular fixed direction. Instead, the labels are used to reflect relative locations and/or directions between various portions of an object.

Data processing may include data buffering, aligning incoming data from multiple communication lanes, forward error correction (FEC), etc. For example, data may be received by an analog front end (AFE), which can prepare the incoming data for digital processing. The digital portion of the transceivers (e.g., digital signal processor (DSP)) may provide skew management, equalization, reflection cancellation, and/or other functions. It is to be appreciated that the process described herein can provide many benefits, including saving both power and cost.

Moreover, the terms “system,” “component,” “module,” “interface,” “model,” or the like are generally intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on a controller and the controller can be a component. One or more components may reside within a process and/or thread of execution, and a component may be localized on one computer and/or distributed between two or more computers.

Unless explicitly stated otherwise, each numerical value and range may be interpreted as being approximate, as if the word “about” or “approximately” preceded the value of the value or range. Signals and corresponding nodes or ports might be referred to by the same name and are interchangeable for purposes here.

While embodiments may have been described with respect to circuit functions, the embodiments of the subject matter disclosed herein are not limited. Possible implementations may be embodied in a single integrated circuit, a multi-chip module, a single card, SoC, or a multi-card circuit pack. As would be apparent to one skilled in the art, the various embodiments might also be implemented as part of a larger system. Such embodiments may be employed in conjunction with, for example, a digital signal processor, microcontroller, field-programmable gate array, application-specific integrated circuit, or general-purpose computer.

As would be apparent to one skilled in the art, various functions of circuit elements may also be implemented as processing blocks in a software program. Such software may be employed in, for example, a digital signal processor, microcontroller, or general-purpose computer. Such software may be embodied in the form of program code embodied in tangible media, such as magnetic recording media, optical recording media, solid-state memory, floppy diskettes, CD-ROMs, hard drives, or any other non-transitory machine-readable storage medium, that when the program code is loaded into and executed by a machine, such as a computer, the machine becomes an apparatus for practicing the subject matter disclosed herein. When implemented on a general-purpose processor, the program code segments combine with the processor to provide a unique device that operates analogously to specific logic circuits. Described embodiments may also be manifest in the form of a bit stream or other sequence of signal values electrically or optically transmitted through a medium, stored magnetic-field variations in a magnetic recording medium, etc., generated using a method and/or an apparatus as described herein.

In some cases, a portion of the LBL and a portion of the central conductive element of the capacitor may be embedded in the semiconductor substrate. For example, a bottom portion of the LBL and/or a bottom portion of the capacitor may extend below a top surface of the substrate. The portions of the LBL and capacitor within the substrate can provide a shorting path between the LBL and capacitor conductive elements, increasing the likelihood for leakage between the LBL and capacitor. If there is leakage between the conductive elements of the LBL and capacitor, any electrical signal put on one can pollute the other. For example, when leakage occurs between the LBL and the capacitor, voltage levels in memory cells can become more difficult for sense amplifiers to sense accurately, and in some cases, the data in the memory cells can become corrupted (e.g., data loss).

In some embodiments, isolation of electrical components of DRAM, such as the word line (WL), bit line (BL) and capacitor (CAP) may be used to prevent a short path and leakage through the semiconductor (e.g., silicon) substrate. For vertically stacked DRAM with vertically oriented BL and CAP modules, the isolation material may be deposited at the bottom of the respective trenches. Process flows with area-selective or bottom-up deposition techniques to create the isolation may be used due to relatively deep and high aspect ratio trenches.

Memory systems can include stacked memory architectures for dynamic random-access memory (DRAM), such as 3D-DRAM, vertically stacked DRAM (VS-DRAM), in addition to planar DRAM. Two conductive components of vertical DRAM include the local bitline (LBL) and a conductive element of the capacitor (e.g., electrodes, conductive plates, armatures).

The systems and methods described herein are based on stacked memory architectures. The disclosure describes mechanisms to reduce the electrical connectivity between the LBL and the capacitor (e.g., increase electrical separation, increase electrical isolation between the LBL and the capacitor).

In some embodiments, bottom isolation (e.g., for LBL and capacitor) may be implemented to minimize LBL-to-substrate and/or capacitor-to-substrate shorting, which can reduce leakage. For vertically stacked memory, relatively deep (>5 um) and/or high aspect ratio (>50:1) trenches can increase the complexity of forming bottom isolation. However, the systems and methods described herein may be implemented independent of trench depth and/or trench aspect ratios.

In some embodiments, creation of a wider gap (e.g., bottom tier gap) between a bottom-most semiconductor tier and the substrate may be implemented. In some cases, a semiconductor tier-to-tier separation may include a relatively thin sacrificial semiconductor tier, where the bottom tier gap may be formed based on a semiconductor thinning step.

The systems and methods described herein provide mechanisms for reducing the portion of the LBL and the capacitor that is embedded in the substrate. In some cases, the mechanisms include positioning a bottom portion of the LBL level with the top surface of the substrate or above the top surface of the substrate. Similarly, the mechanisms include positioning a bottom portion of the conductive element of the capacitor level with the top surface of the substrate or above the top surface of the substrate.

In some embodiments, usage of area selective deposition (ASD) or flowable chemical vapor deposition (FCVD) may be used to create the bottom isolation. For example, ASD and/or FCVD of dielectric into a bottom gap may be performed to form a relatively wide gap between the bottom-most semiconductor tier and the substrate. Based on the systems and methods described herein, full substrate isolation for LBL and CAP may be obtained.

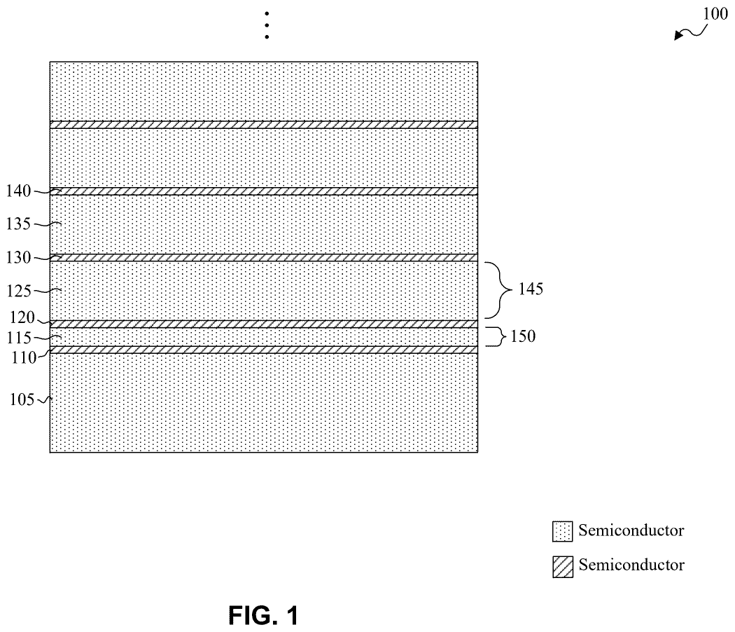

FIG. 1 illustrates an example structure 100 in accordance with one or more implementations as described herein. In some configurations, one or more aspects of structure 100 may be implemented by or in conjunction with a fabrication device and/or a process of a fabrication device.

Structure 100 may include substrate 105 and layers of materials stacked on substrate 105. As shown, layers of different materials may be stacked in an interleaved fashion on substrate 105. For example, semiconductor 110 (e.g., semiconductor, semiconductor alloy) may be formed on substrate 105, semiconductor 115 on semiconductor 110, semiconductor 120 on semiconductor 115, semiconductor 125 on semiconductor 120, semiconductor 130 on semiconductor 125, semiconductor 135 on semiconductor 130, semiconductor 140 on semiconductor 135, etc.

It is noted that the elements of a stacked memory may be built on top of a substrate (e.g., semiconductor substrate, silicon substrate). In some cases, the cross-section side view of the stacked memory may show the substrate on the bottom as a base layer. Thus, the bottom of the LBL may be the portion of the LBL nearest the substrate, while the top of the LBL may be a portion of the LBL farthest from the substrate. Similarly, the bottom of the capacitor may be the portion of the capacitor closest to the substrate, and the top of the capacitor may be a portion of the capacitor furthest from the substrate, etc.

A memory stack may be configured as a multi-tiered structure. Structure 100 may be formed to fabricate the layers of a memory stack. For example, at some point in its fabrication, a memory stack can include substrate 105 and the interleaved layers stacked on substrate 105. A stacked memory may include a number of tiers or layers. A given tier adjacent to the LBL may represent a transistor of a memory cell, and a corresponding tier adjacent to the central conductive element of the capacitor may represent an individual capacitor of that memory cell.

In some cases, the depicted semiconductor layers (e.g., 115, 125, 135) may include a first semiconductor (e.g., silicon), while the other semiconductor layers (e.g., 110, 120, 130, 140) may include a second semiconductor (e.g., silicon germanium (SiGe). Although different semiconductors may be used, silicon may be used in the description to represent the first semiconductor layers, and SiGe may be used in the description to represent the second semiconductor layers.

As shown in the top layers, the layers of silicon and SiGe may form a periodicity between the relative thickness of the SiGe layers and the thickness of the silicon layers. However, towards the bottom layers, a relatively thin layer of silicon (e.g., semiconductor 115) may be deposited between semiconductor 110 and semiconductor 120. As shown, semiconductor 110 may be a first SiGe layer, a bottom-most SiGe layer, or a first SiGe layer above substrate 105, etc. Semiconductor 120 may be the next SiGe layer or second SiGe layer above semiconductor 110 (e.g., above the bottom-most SiGe layer).

As depicted, semiconductor 115 may be fabricated to be thinner than one or more other silicon layers (e.g., thinner than all other silicon layers). Semiconductor 115 may have a first thickness (e.g., thickness 150) and the one or more other silicon layers (e.g., semiconductor 125, semiconductor 135, etc.) may have a second thickness (e.g., thickness 145) that is greater than the first thickness. The one or more other silicon layers may be formed with a relatively uniform thickness (e.g., thickness 145). Similarly, the SiGe layers may be formed with a relatively uniform thickness that is less than thickness 150 and thickness 145. For example, semiconductor 115 may have a thickness that falls within the range of 10-55 nanometers, while the one or more other silicon layers (e.g., semiconductor 125, semiconductor 135, etc.) may have a thickness that falls within the range of 30-100 nanometers. In some cases, the SiGe layers (e.g., semiconductor 110, semiconductor 120, semiconductor 130, semiconductor 140, etc.) may have a thickness within the range of 5-20 nanometers.

The relatively thin silicon layer, semiconductor 115, may be referred to as a sacrificial semiconductor tier or sacrificial silicon layer. The systems, methods, and devices described herein for forming electrical isolation structures between a substrate layer (e.g., substrate 105) and components of a stacked memory (e.g., wordlines, bitlines, capacitors) may be based on forming a wider bottom tier (e.g., a bottom semiconductor tier wider than other semiconductor tiers). Forming the relatively thin semiconductor 115 between the semiconductor 110 and semiconductor 120 enables formation of the wider bottom tier.

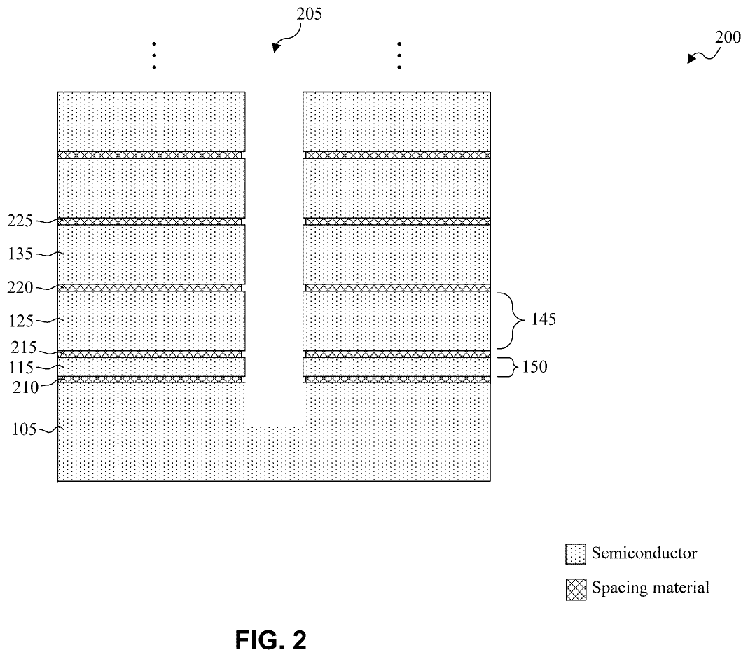

FIG. 2 illustrates an example structure 200 in accordance with one or more implementations as described herein. In some configurations, one or more aspects of structure 200 may be implemented by or in conjunction with a fabrication device and/or a process of a fabrication device. One or more aspects of structure 200 may be based on aspects of structure 100.

In the illustrated example, trench 205 may be formed in the layers of structure 200. As shown, trench 205 may extend down into substrate 105. In some cases, the SiGe layers of structure 100 may be removed. As shown, layers of spacing material (e.g., spacing 210, spacing 215, spacing 220, spacing 225) may be formed between the depicted semiconductor layers (e.g., semiconductor 115, semiconductor 125, semiconductor 135, etc.).

In some cases, trench 205 may be filled with the conductive material of an LBL or capacitor. With some stacked memory systems, a portion of the LBL and a portion of the conductive element of the capacitor may be embedded in the semiconductor substrate (e.g., where trench 205 extends into substrate 105). For example, a bottom portion of the LBL and/or a bottom portion of the capacitor may extend below a top surface of the substrate. The portions of the LBL and capacitor within the substrate can provide a shorting path between the LBL and capacitor conductive elements, increasing the likelihood for leakage between the LBL and capacitor. If there is leakage between the conductive elements of the LBL and capacitor, any electrical signal put on one can pollute the other. For example, when leakage occurs between the LBL and the capacitor, voltage levels in memory cells can become more difficult for sense amplifiers to sense accurately, and in some cases, the data in the memory cells can become corrupted (e.g., data loss).

The process to add an insulating barrier between the conductor of the LBL and substrate 105 and/or between the conductor of the capacitor and the substrate may be based on removing the SiGe layers (e.g., semiconductor 110, semiconductor 120, semiconductor 130, semiconductor 140, etc.). In some cases, the process of forming a wider bottom tier may be based on removing the SiGe layers. In some cases, the spacing material may be deposited between the semiconductor layers to form a pillar structure that maintains structural stability during fabrication of the memory stack.

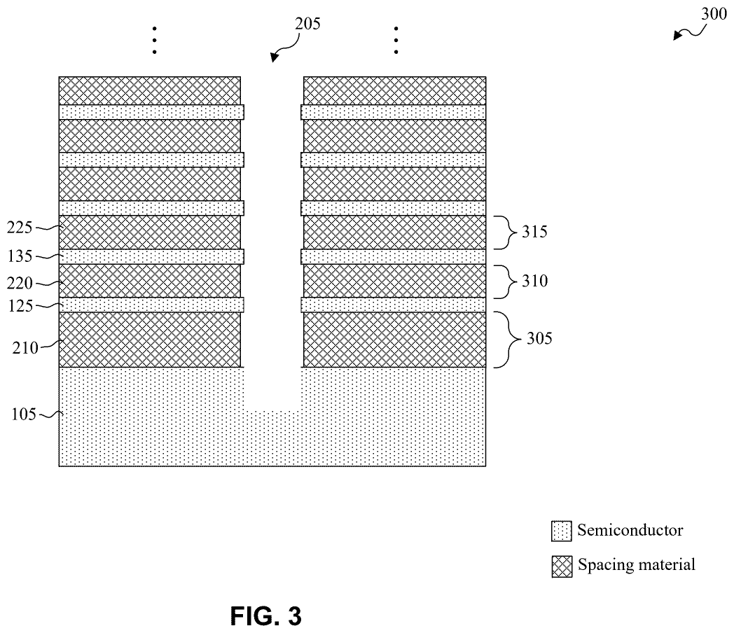

FIG. 3 illustrates an example structure 300 in accordance with one or more implementations as described herein. In some configurations, one or more aspects of structure 300 may be implemented by or in conjunction with a fabrication device and/or a process of a fabrication device. One or more aspects of structure 300 may be based on aspects of structure 200.

In the illustrated example, layers of semiconductor 125, semiconductor 135, etc., may be formed based on a thinning process configured to thin the semiconductor layers of structure 200 to a desired thickness. As shown, semiconductor 115 may be removed. For example, due to semiconductor 115 being thinner than other semiconductor layers, the thinning process may remove semiconductor 115. In some cases, removing the SiGe layers may result in gaps between the layers of silicon. These gaps may enable access to top and bottom surfaces of the silicon layers to thin down the silicon layers to some desired thickness. The silicon layers may be thinned based on a mechanical process (e.g., mechanical grinding), a chemical process (e.g., chemical mechanical planarization), wet etching, dry etching, etc.

In some embodiments, a wide bottom gap with the substrate may be formed based on the thinning of the semiconductor layers. In some cases, the thickness of the semiconductor layers may be based on electrical properties, insulative properties, etc. As shown, the upper silicon layers (e.g., thicker silicon layers such as semiconductor 125, semiconductor 135) may get thinned down to some desired thickness. However, the bottom silicon layer, semiconductor 115 (e.g., sacrificial silicon layer) may be consumed based on the silicon thinning process. Based on semiconductor 115 getting consumed, the wider bottom tier may be formed, which increases the electrical isolation between the LBL and substrate 105 and/or between the capacitor and substrate 105. In the depicted example, spacing 210 may represent spacing 210 and spacing 215, where they appear to have merged due to the removal of semiconductor 115.

Based on the removal of semiconductor 115, the space between semiconductor 125 and substrate 105 may be greater than the space between other semiconductors. For example, as shown, gap 305 may be greater than gap 310, gap 315, etc. As shown, gap 305 may represent the distance between semiconductor 125 and substrate 105; gap 310 the distance between semiconductor 135 and semiconductor 125; and gap 315 the distance between semiconductor 135 and the next semiconductor above semiconductor 135, etc.

In some cases, gap 305 may have a thickness somewhere in the range 70 nm to 120 nm (e.g., 95 nm). Other spans between semiconductors (e.g., gap 310, gap 315) may have a thickness somewhere in the range 40 nm to 90 nm (e.g., 65 nm).

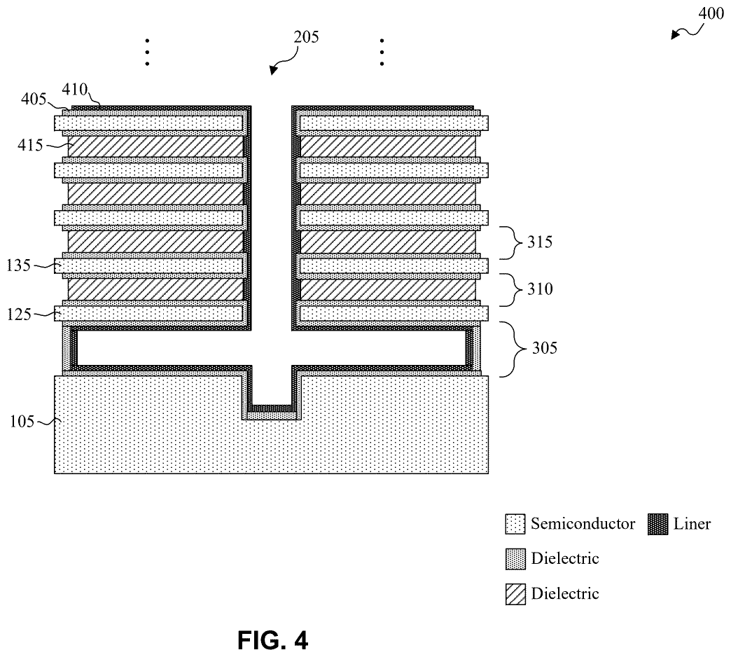

FIG. 4 illustrates an example structure 400 in accordance with one or more implementations as described herein. In some configurations, one or more aspects of structure 400 may be implemented by or in conjunction with a fabrication device and/or a process of a fabrication device. One or more aspects of structure 400 may be based on aspects of structure 300.

In the illustrated example, one or more materials may be deposited on structure 400. In some cases, one or more dielectrics may be deposited on structure 400. For example, dielectric 405 may be deposited over semiconductor tiers of structure 400 (e.g., semiconductor 125, semiconductor 135, etc.). In some cases, a liner material may be deposited over one or more surfaces of structure 400. For example, liner 410 may be deposited over surfaces of structure 400, including surfaces of dielectric 405. As shown, dielectric 415 (e.g., a second dielectric) may be deposited over one or more surfaces of structure 400. In some cases, line 410 may include a dielectric material.

In some cases, some deposited materials (e.g., liner 410 and/or dielectric 415) may be configured as non-growth materials. For example, when an isolation material is added to gap 305 (e.g., based on ASD, FCVD, etc.), the configuration of liner 410 and/or dielectric 415 may inhibit or slow the growth of the isolation material, resulting in a first portion of the isolation material growing towards a second portion of the isolation material, etc. (e.g., but not necessarily towards a non-growth material). In some embodiments, a one-step ASD isolation process may be used. After the semiconductor is thinned, a liner (e.g., liner 410) may be deposited and trimmed, with a dielectric fill and etched back used prior to the lateral ASD forming the isolation.

In some cases, liner 410 may be deposited to control the growth of the isolation layer on sidewalls of structure 400 (e.g., sidewalls of trench 205). The isolation material may then fill the space such that the bottom gap space is filled with the isolation material (e.g., after an etch back). A deposition (e.g., lateral ASD) may then be performed that is insensitive to trench depth variations. In some embodiments, a liner trim (e.g., removal of liner 410) may be performed.

Because gap 305 is wider than the other gaps (e.g., upper gaps such as gap 310, gap 315), gap 305 remains empty (e.g., relatively empty) when a material (e.g., dielectric 415) is deposited, when material is etched or removed, while the other gaps (e.g., gap 310, gap 315) are filled with the material (e.g., dielectric 415). Filling the upper gaps and leaving gap 305 empty allows gap 305 to be filled with isolation material for the bottom layer.

To reduce the electrical connectivity between the LBL and the substrate, a bottom transistor tier (e.g., transistor tier closest to the substrate) may be configured to be wider than other transistor tiers above the bottom transistor tier, resulting in gap 305 being wider than other gaps (e.g., gap 310, gap 315). Similarly, to reduce the electrical connectivity between the capacitor and the substrate, a bottom capacitor tier (e.g., gap 305 based on a wider capacitor electrode tier closest to the substrate) may be configured to be wider than other capacitor tiers above the bottom capacitor tier.

The wider bottom tier can increase the inter-tier gap between an LBL and substrate 105, increasing the insulative effect between the LBL and substate 105, and reducing the electrical connectivity between the LBL and a capacitor associated with substrate 105. Similarly, to reduce the electrical connectivity between the capacitor and substrate 105 (e.g., and between the LBL and the capacitor), a bottom capacitor tier (e.g., capacitor tier closest to the substrate) may be configured to be wider than another capacitor tier above the bottom capacitor tier. The wider bottom tier increases the inter-tier gap between the capacitor and substrate 105, increasing the insulative effect between the capacitor and substate 105 and reducing the electrical connectivity between the LBL and the capacitor. In some embodiments, a wordline (WL) may be formed within the wide bottom gap (e.g., gap 305). The space of the wide bottom gap may remain empty after the WL formation.

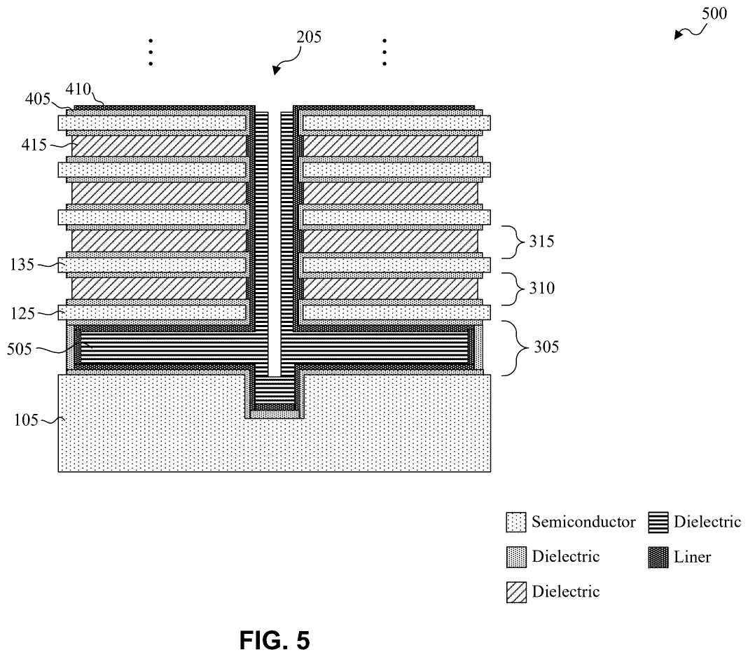

FIG. 5 illustrates an example structure 500 in accordance with one or more implementations as described herein. In some configurations, one or more aspects of structure 500 may be implemented by or in conjunction with a fabrication device and/or a process of a fabrication device. One or more aspects of structure 500 may be based on aspects of structure 400.

In the illustrated example, an isolation material (e.g., dielectric 505) may be deposited in trench 205, filling portions of gap 305 and/or bottom portions of trench 205. It is noted that the material of liner 410 may be the same material or a different material from the material of dielectric 405. In some cases, the dielectric 405 may be the same material or a different material from the material of dielectric 415. The material of liner 410 may be the same material or a different material from the material of dielectric 415. In some examples, dielectric 505 may include an isolation material that is different from dielectric 405, liner 410, and/or dielectric 415. In some cases, dielectric 505 may include a dielectric material that is the same or similar to dielectric 405, liner 410, and/or dielectric 415, but dielectric 505 may be configured to behave differently from liner 410.

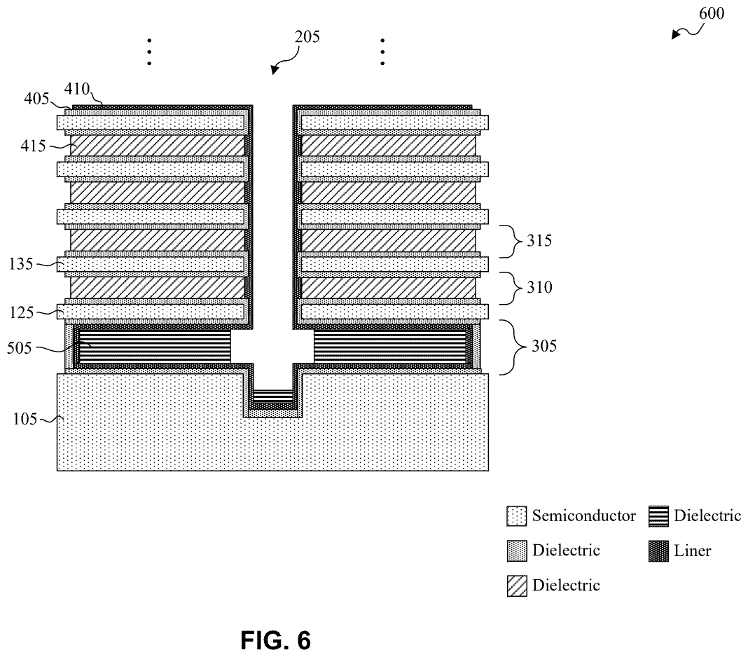

FIG. 6 illustrates an example structure 600 in accordance with one or more implementations as described herein. In some configurations, one or more aspects of structure 600 may be implemented by or in conjunction with a fabrication device and/or a process of a fabrication device. One or more aspects of structure 600 may be based on aspects of structure 500.

In the illustrated example, at least a portion of the isolation material (e.g., dielectric 505) may be removed or etched. Based on the removal process, dielectric 505 may remain in gap 305 and/or within a bottom portion of trench 205 (e.g., portion of trench 205 nearest substrate 105, portion of trench 205 within substrate 105 or below a top surface of substrate 105).

A deposition process may be used to grow dielectric 505 on itself, but inhibit its growth on non-growth material (e.g., liner 410, dielectric 415). The deposition process may include ASD and/or FCVD. In some cases, the chemistry of dielectric 505 may be configured so that dielectric 505 grows on itself, but not on non-growth material. In some cases, dielectric 505 in gap 305 and in the bottom portion of trench 205 may grow towards itself. For example, dielectric 505 may grow laterally and connect in the middle of gap 305. Similarly, dielectric 505 may grow upwards from the bottom portion of trench 205 towards the portions of dielectric 505 growing laterally in gap 305.

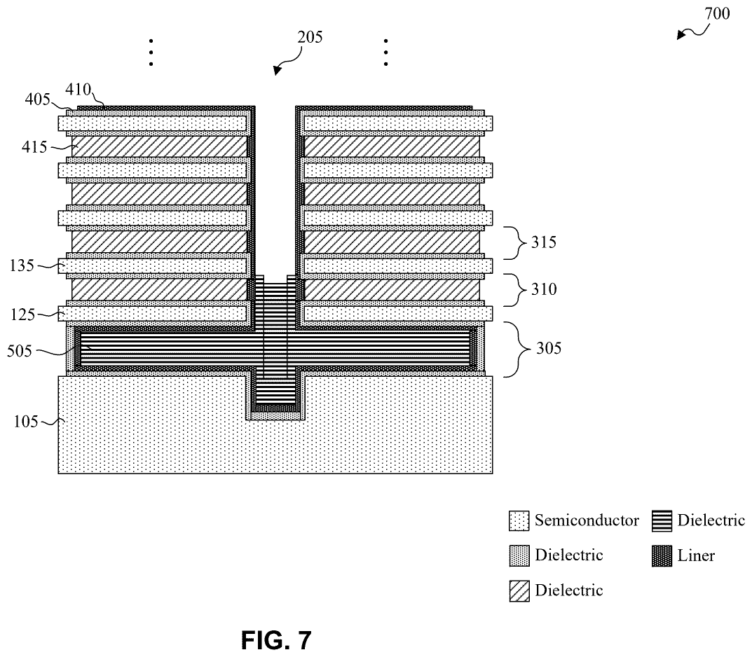

FIG. 7 illustrates an example structure 700 in accordance with one or more implementations as described herein. In some configurations, one or more aspects of structure 700 may be implemented by or in conjunction with a fabrication device and/or a process of a fabrication device. One or more aspects of structure 700 may be based on aspects of structure 600.

In the illustrated example, a deposition process (e.g., ASD, FCVD) may be used to grow dielectric 505 on itself, but not grow on a non-growth material (e.g., liner 410, dielectric 415). Dielectric 505 may be configured to grow on and towards itself, but not on non-growth material. As shown, dielectric 505 in gap 305 may grow laterally and connect in the middle of gap 305. Similarly, dielectric 505 may grow upwards from the bottom portion of trench 205 towards the portions of dielectric 505 growing laterally in gap 305. In some cases, dielectric 505 may grow above gap 305. Based on the deposition, removal, and controlled growth of dielectric 505, a material (e.g., a conductive material) deposited in trench 205 on and above dielectric 505 may be electrically isolated from substrate 105.

In some examples, the mechanisms for decreasing the electrical connectivity between an LBL and capacitor of a stacked memory may include adding insulating material (e.g., insulative barrier, dielectric 505) between a bottom of the LBL and substrate 105 and/or adding insulating material between the bottom of the capacitor and substrate 105. In some cases, the insulating material may be deposited using one or more deposition techniques (e.g., area-selective deposition (ASD), selective chemical vapor deposition (SCVD), flowable CVD (FCVD), etc.).

In some embodiments, the deposition of dielectric 505 may be based on area selective deposition (ASD), which may include a deposition of a film selectively deposited on growth regions (e.g., dielectric 505 after being etched back), and no deposition on non-growth regions. In some embodiments, ASD may be a chemical patterning that operates based on surface compositions.

ASD can include a technique to grow material on selected regions of a semiconductor device (e.g., stacked memory) and not on other regions. With ASD, some material may be deposited on a selected growth region, but not deposited on a non-growth area (e.g., based on chemistry of materials, chemical interactions of materials, etc.). Based on ASD, the mechanisms disclosed herein may provide bottom-up growth of one or more materials to isolate the LBL and/or capacitor electrically from substrate 105, increasing the electrical isolation between the LBL and capacitor.

In some examples, the deposition of dielectric 505 filling a bottom portion of trench 205 (e.g., portion of trench 205 below a top surface of substrate 105) and filling gap 305 (e.g., including, in some cases, filling a portion of trench 205 above gap 305) may be based on deposition of a flowable material (e.g., flowable dielectric, flowable configuration of dielectric 505). For example, deposition of dielectric 505 may be based on FCVD. In some cases, dielectric 505 may be deposited to trench 205 (e.g., after removal of liner 410), where dielectric 505 flows into trench 205, percolating to the bottom of trench 205, flowing into and filling gap 305. In some embodiments, FCVD may include a deposition of a viscous polymer (e.g., dielectric 505), which may flow to the bottom of trench 205 and may use a post-deposition annealing to harden. For example, FCVD may be used to deposit a thin layer of a flowable material, where the material flows into trench 205 (e.g., a bottom area of the trench) and plugs the bottom of trench 205.

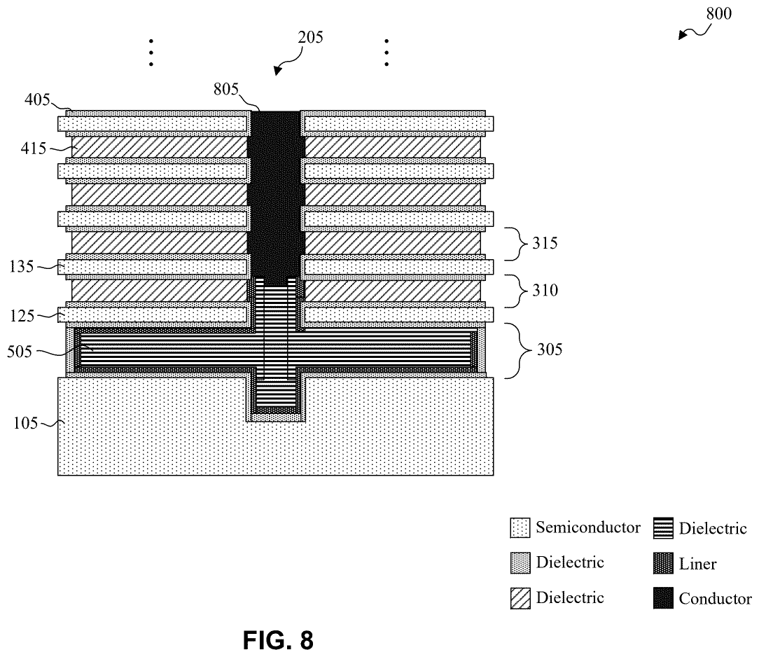

FIG. 8 illustrates an example structure 800 in accordance with one or more implementations as described herein. In some configurations, one or more aspects of structure 800 may be implemented by or in conjunction with a fabrication device and/or a process of a fabrication device. One or more aspects of structure 800 may be based on aspects of structure 700.

In the illustrated example, liner 410 may be removed (e.g., above an upper surface of dielectric 505) and conductor 905 may be added to trench 205. For example, a conductive material (e.g., conductor 805) may be deposited in trench 205 on and above dielectric 505. Conductor 805 may include a metal and/or semiconductor (e.g., tungsten, polysilicon). In some cases, liner 410 may be removed prior to adding conductor 805. For example, after the growth of dielectric 505 depicted in FIG. 7, liner 410 may be removed (e.g., etched). Conductor 805 may then be added after removing liner 410.

Based on the controlled application of dielectric 505, conductor 805 is electrically isolated from the substrate 105. Because conductor 805 is no longer in direct contact with substrate 105, conductor 805 is electrically isolated from other conductive material that may be in contact with substrate 105. For example, conductor 805 may be configured as a local bitline, and dielectric 505 may electrically isolate the LBL from a conductive element of a capacitor in contact with substrate 105. In some cases, both the LBL (e.g., conductor 805) and the conductive element of the capacitor may be electrically isolated from substrate 105 based on respective portions of isolation material, further increasing the isolation between the LBL and capacitor.

As shown, at least a portion of liner 410 may be removed (e.g., prior to adding conductor 805). In some embodiments, trench 205 may be etched back (e.g., after photolithography), and liner 410 may be trimmed back with the isolation material (e.g., dielectric 505) acting as an etch stop. LBL deposition (e.g., conductor 805) may be isolated from substrate 105 based on the ASD isolation. In some embodiments, FCVD may be used in place of ASD, and may reduce the steps used compared to those for ASD. In some embodiments, after the wordline is formed, liner 410 may be deposited with flowable CVD performed to deposit the isolation material, which may be annealed to harden the isolation material. Liner 410 may then be trimmed back before depositing conductor 805.

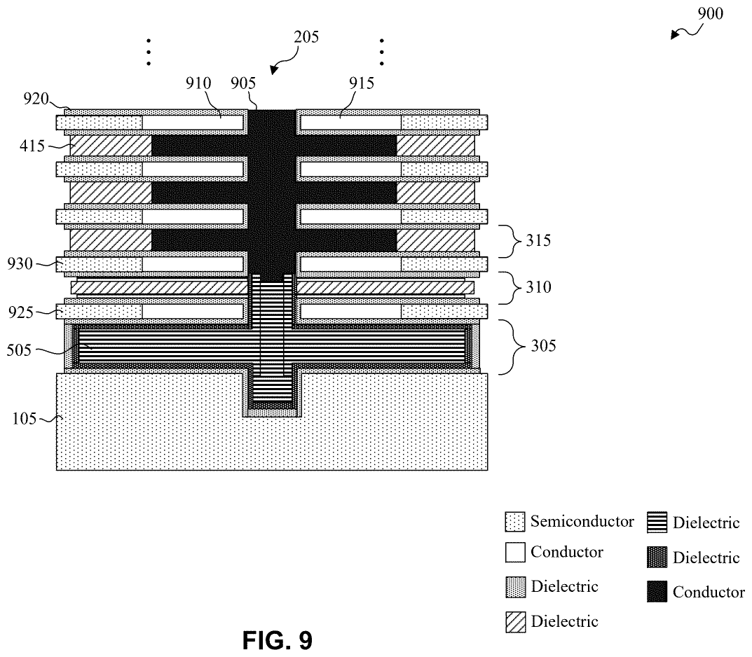

FIG. 9 illustrates an example structure 900 in accordance with one or more implementations as described herein. In some configurations, one or more aspects of structure 900 may be implemented by or in conjunction with a fabrication device and/or a process of a fabrication device. One or more aspects of structure 900 may be based on aspects of structure 800.

In a cross-section side view of a stacked memory, the conductive element of the LBL may be depicted as a column or pillar of some conductive material such as conductor 805 (e.g., metal, semiconductor, tungsten, polysilicon, etc.). Similarly, the conductive element of a capacitor may be depicted as a central column or pillar of some conductive material (e.g., metal, semiconductor, tungsten, polysilicon, etc.) with fingers that extend from the central conductive element. Each finger may represent an electrode for a given memory cell.

In the illustrated example, liner 410 may be removed (e.g., above an upper surface of dielectric 505) and conductor 905 may be added to trench 205 (e.g., based on the partial removal of liner 410). As shown, structure 900 may include additional fingers of conductive material (e.g., conductor 910, conductor 915, etc.) that extend into portions of conductor 905. As shown, portions of conductor 905 may extend between these additional fingers of conductive material. Conductor 910, conductor 915, and the other additional fingers of conductive material depicted in FIG. 9 may be configured as electrodes of respective memory cells. As shown, the additional fingers of conductive material (e.g., conductor 910, conductor 915) may connect to respective semiconductors (e.g., semiconductor 925, semiconductor 930, etc.) of the respective memory cells. In some cases, a dielectric material (e.g., dielectric 920) may be deposited over the additional fingers of conductive material (e.g., conductor 910, conductor 915, etc.) to separate conductor 905 from these additional fingers of conductive material.

Based on the controlled application of dielectric 505, conductor 905 may be electrically isolated from the substrate 105. Because conductor 905 is no longer in direct contact with substrate 105, conductor 905 is electrically isolated from other conductive material that may be in contact with substrate 105. For example, conductor 905 may be configured as a conductive element of a capacitor, and dielectric 505 may electrically isolate conductor 905 from a conductive element of an LBL in contact with substrate 105. In some cases, both the LBL and the conductive element of the capacitor may be electrically isolated from substrate 105 based on respective portions of isolation material in the respective trenches of the LBL and capacitor, further increasing the isolation between the LBL and capacitor.

In some configurations, a first process may include forming a barrier of isolation material (e.g., dielectric 505) in a trench of an LBL and topping the trench of the LBL with conductive material (e.g., conductor 905), and a second process before or after the first process may include forming a barrier of isolation material (e.g., dielectric 505) in a trench of a capacitor and topping the trench of the capacitor with conductive material (e.g., conductor 905).

In some cases, dielectric 505 may be deposited in a trench of a capacitor and the trench of an LBL simultaneously or concurrently. For example, deposition of dielectric 505 in an LBL trench and a capacitor trench may be part of the same deposition operation, where both trenches are filled concurrently (e.g., at the same time, relatively near the same time, within a time period that is part of a single deposition operation). In some cases, isolation material may be removed from both trenches concurrently (e.g., at the same time, relatively near the same time, within a time period of a single removal/etching operation). In some cases, conductive material (e.g., conductor 805, conductor 905) may be added to both trenches concurrently (e.g., at the same time, relatively near the same time, within a time period of a single conductive filling operation).

In some embodiments, ASD may be used to form isolation in the capacitor. A mold may be formed within gap 310, with a bottom space remaining empty. A liner deposition step (e.g., liner 410) may stop isolation material growth on the sidewalls of trench 205. A dielectric fill may introduce isolation material into the bottom gap space, which may then be etched back. A lateral ASD may then be performed, which is insensitive to variations in the trench depth. A capacitor may then be formed on top of the isolation material, separated from substrate 105.

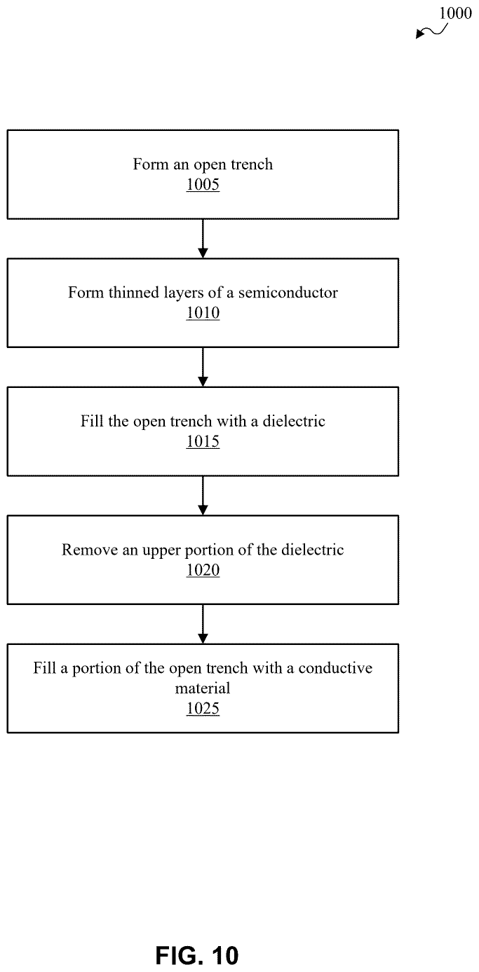

FIG. 10 depicts a flow diagram illustrating an example method 1000 associated with the disclosed systems, in accordance with example implementations described herein. In some configurations, one or more aspects of method 1000 may be implemented by or in conjunction with a fabrication device and/or a process of a fabrication device. The depicted method 1000 is just one implementation, and one or more operations of method 1000 may be rearranged, reordered, omitted, and/or otherwise modified such that other implementations are possible and contemplated.

At 1005, method 1000 may include forming an open trench. For example, method 1000 may include forming an open trench between layers of a semiconductor.

At 1010, method 1000 may include forming thinned layers of a semiconductor. For example, method 1000 may include forming thinned layers of the semiconductor based on a thinning process, the thinning process forming a gap layer based on the thinning process removing a bottom layer of the semiconductor.

At 1015, method 1000 may include filling the open trench with a dielectric. For example, method 1000 may include filling the open trench with a dielectric, the dielectric covering exposed surfaces of the open trench, including the thinned layers of the semiconductor.

At 1020, method 1000 may include removing an upper portion of the dielectric. For example, method 1000 may include removing an upper portion of the dielectric based on a removal process, the dielectric remaining in the gap layer and a bottom portion of the open trench based on the removal process.

At 1025, method 1000 may include filling a portion of the open trench with a conductive material. For example, method 1000 may include filling a portion of the open trench above the dielectric with a conductive material.

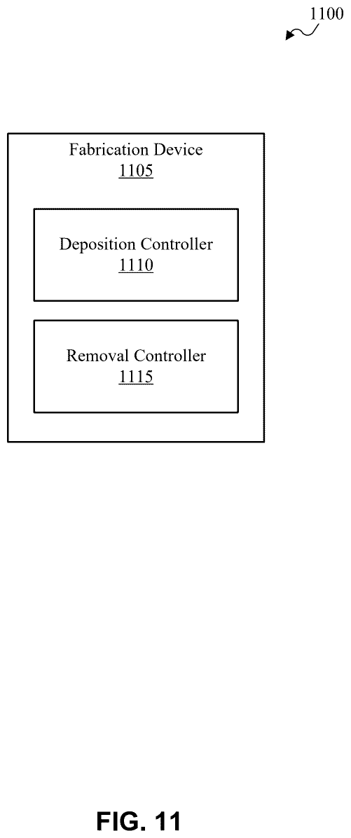

FIG. 11 illustrates an example system 1100 in accordance with one or more implementations as described herein. As shown, system 1100 may include fabrication device 1105. Fabrication device 1105 may include any one or combination of logic (e.g., logical circuit), hardware (e.g., processing unit, memory, storage), software, firmware, and the like, that enable fabrication device 1105 to provide the systems and methods described herein of selective metal deposition for memory cell transistors.

In the illustrated example, fabrication device 1105 may include deposition controller 1110 and removal controller 1115. In some cases, deposition controller 1110 and/or removal controller 1115 may include any one or combination of logic (e.g., logical circuit), hardware (e.g., processing unit, memory, storage), software, firmware, and the like.

Deposition controller 1110 may include a control system that manages the parameters of a deposition process, where a thin layer of material is deposited onto a wafer to create the electronic components within an integrated circuit (IC). Deposition controller 1110 may regulate factors like temperature, gas flow, pressure, and plasma conditions to ensure the deposited film has the desired properties and thickness for optimal device performance. Deposition controller 1110 may provide area-selective deposition (ASD); chemical vapor deposition (CVD), where precursor gases react on the wafer surface to form a solid film; flowable CVD; selective CVD; plasma enhanced CVD (PECVD), where plasma is used to enhance chemical reactions, enabling deposition at lower temperatures; atomic layer deposition (ALD), where a single layer of atoms may be deposited at a time; and the like.

Removal controller 1115 may control the process of removing material from a wafer during etching, which may include dry etching and/or plasma etching, ensuring that only the desired areas are removed with the correct depth and precision to create the desired circuit features on a given chip. Removal controller 1115 may manage the rate and selectivity of material removal during the etching step.

In the examples described herein, the configurations and operations are example configurations and operations, and may involve various additional configurations and operations not explicitly illustrated. In some examples, one or more aspects of the illustrated configurations and/or operations may be omitted. In some embodiments, one or more of the operations may be performed by components other than those illustrated herein. Additionally, or alternatively, the sequential and/or temporal order of the operations may be varied.

Certain embodiments may be implemented in one or a combination of hardware, firmware, and software. Other embodiments may be implemented as instructions stored on a computer-readable storage device, which may be read and executed by at least one processor to perform the operations described herein. A computer-readable storage device may include any non-transitory memory mechanism for storing information in a form readable by a machine (e.g., a computer). For example, a computer-readable storage device may include read-only memory (ROM), random-access memory (RAM), magnetic disk storage media, optical storage media, flash-memory devices, and other storage devices and media.

The word “exemplary” may be used herein to mean “serving as an example, instance, or illustration.” Any embodiment described herein as “exemplary” is not necessarily to be construed as preferred or advantageous over other embodiments.

Although an example processing system has been described above, embodiments of the subject matter and the functional operations described herein can be implemented in other types of digital electronic circuitry, or in computer software, firmware, or hardware, including the structures disclosed in this specification and their structural equivalents, or in combinations of one or more of them.

Embodiments of the subject matter and the operations described herein can be implemented in digital electronic circuitry, or in computer software, firmware, or hardware, including the structures disclosed in this specification and their structural equivalents, or in combinations of one or more of them. Embodiments of the subject matter described herein can be implemented as one or more computer programs, i.e., one or more components of computer program instructions, encoded on computer storage medium for execution by, or to control the operation of, information/data processing apparatus. Alternatively, or in addition, the program instructions can be encoded on an artificially generated propagated signal, for example, a machine-generated electrical, optical, or electromagnetic signal, which is generated to encode information/data for transmission to suitable receiver apparatus for execution by an information/data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially generated propagated signal. The computer storage medium can also be, or be included in, one or more separate physical components or media (for example, multiple CDs, disks, or other storage devices).

The operations described herein can be implemented as operations performed by an information/data processing apparatus on information/data stored on one or more computer-readable storage devices or received from other sources.

The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, for example, an FPGA (field programmable gate array) or an ASIC (application specific integrated circuit). The apparatus can also include, in addition to hardware, code that creates an execution environment for the computer program in question, for example code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand alone program or as a component, component, subroutine, object, or other unit suitable for use in a computing environment. A computer program may, but need not, correspond to a file in a file system. A program can be stored in a portion of a file that holds other programs or information/data (for example one or more scripts stored in a markup language document), in a single file dedicated to the program in question, or in multiple coordinated files (for example files that store one or more components, sub programs, or portions of code). A computer program can be deployed to be executed on one computer or on multiple computers that are located at one site or distributed across multiple sites and interconnected by a communication network.

The processes and logic flows described herein can be performed by one or more programmable processors executing one or more computer programs to perform actions by operating on input information/data and generating output. Processors suitable for the execution of a computer program include, by way of example, both general and special purpose microprocessors, and any one or more processors of any kind of digital computer. Generally, a processor will receive instructions and information/data from a read only memory or a random access memory or both. The essential elements of a computer are a processor for performing actions in accordance with instructions and one or more memory devices for storing instructions and data. Generally, a computer will also include, or be operatively coupled to receive information/data from or transfer information/data to, or both, one or more mass storage devices for storing data, for example magnetic, magneto optical disks, or optical disks. However, a computer need not have such devices. Devices suitable for storing computer program instructions and information/data include all forms of non volatile memory, media and memory devices, including by way of example semiconductor memory devices, for example EPROM, EEPROM, and flash memory devices; magnetic disks, for example internal hard disks or removable disks; magneto optical disks; and CD ROM and DVD-ROM disks. The processor and the memory can be supplemented by, or incorporated in, special purpose logic circuitry.

Embodiments of the subject matter described herein can be implemented in a computing system that includes a back end component, for example as an information/data server, or that includes a middleware component, for example an application server, or that includes a front end component, for example a client computer having a graphical user interface or a web browser through which a user can interact with an embodiment of the subject matter described herein, or any combination of one or more such back end, middleware, or front end components. The components of the system can be interconnected by any form or medium of digital information/data communication, for example a communication network. Examples of communication networks include a local area network (“LAN”) and a wide area network (“WAN”), an inter-network (for example the Internet), and peer-to-peer networks (for example ad hoc peer-to-peer networks).

The computing system can include clients and servers. A client and server are generally remote from each other and typically interact through a communication network. The relationship of client and server arises by virtue of computer programs running on the respective computers and having a client-server relationship to each other. In some embodiments, a server transmits information/data (for example an HTML page) to a client device (for example for purposes of displaying information/data to and receiving user input from a user interacting with the client device). Information/data generated at the client device (for example a result of the user interaction) can be received from the client device at the server.

While this specification contains many specific embodiment details, these should not be construed as limitations on the scope of any embodiment or of what may be claimed, but rather as descriptions of features specific to particular embodiments. Certain features that are described herein in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain embodiments, multitasking and parallel processing may be advantageous.

Many modifications and other examples as set forth herein will come to mind to one skilled in the art to which these embodiments pertain having the benefit of the teachings presented in the foregoing descriptions and the associated drawings. Therefore, it is to be understood that the embodiments are not to be limited to the specific embodiments disclosed and that modifications and other embodiments are intended to be included within the scope of the appended claims. Although specific terms are employed herein, they are used in a generic and descriptive sense only and not for purposes of limitation.

What is claimed:

1. A memory device comprising:
a substrate layer;
layers of a semiconductor formed horizontally over the substrate layer;
a gap layer formed horizontally between the substrate layer and a first layer of the layers of the semiconductor;
an open trench vertically bifurcating the layers of the semiconductor;
a dielectric that fills the gap layer and a bottom portion of the open trench; and
a conductor that fills an upper portion of the open trench.

2. The memory device of claim 1, further comprising:
a second open trench that vertically bifurcates second layers of the semiconductor;
a second gap layer and a bottom portion of the second open trench filled with the dielectric; and
a second conductor that fills an upper portion of the second open trench.

3. The memory device of claim 2, wherein:
the conductor of the open trench forms a local bitline, and
the second conductor of the second open trench forms a conductive element of a capacitor.

4. The memory device of claim 2, wherein the first layer and the second layers of the second open trench are thinned according to a same process step.

5. The memory device of claim 2, wherein the gap layer and bottom portion of the open trench and the second gap layer and bottom portion of the second open trench are filled in a same process step.

6. The memory device of claim 2, wherein:
the gap layer is formed based on removing a bottom layer of the layers of the semiconductor; and
the second gap layer is formed based on removing a bottom layer of the second layers of the semiconductor.

7. The memory device of claim 1, wherein:
a first layer of a second semiconductor is formed on the substrate layer;
a bottom layer of the semiconductor is formed on the first layer of the second semiconductor;
a second layer of the second semiconductor is formed on the bottom layer of the semiconductor; and
a second layer of the semiconductor is formed on the second layer of the second semiconductor.

8. The memory device of claim 7, wherein:
the first layer of the second semiconductor is formed on the substrate layer with a first thickness between 5 and 20 nanometers;
the bottom layer of the semiconductor is formed on the first layer of the second semiconductor with a second thickness between 10 and 55 nanometers; and
the second layer of the semiconductor is formed on the second layer of the second semiconductor with a third thickness between 30 and 100 nanometers.

9. The memory device of claim 7, wherein:
the semiconductor comprises silicon, and
the second semiconductor comprises silicon germanium.

10. The memory device of claim 1, wherein a filling process of the dielectric is based on at least one of area-selective deposition or flowable chemical vapor deposition.

11. A method comprising:
forming an open trench between layers of a semiconductor;
performing a thinning process that includes forming thinned layers of the semiconductor the thinning process and forming a gap layer by removing a bottom layer of the semiconductor;
filling the open trench with a dielectric that covers exposed surfaces of the open trench, including the thinned layers of the semiconductor;
performing a removal process that includes removing an upper portion of the dielectric, the dielectric remaining in the gap layer and a bottom portion of the open trench; and
filling a portion of the open trench above the dielectric with a conductive material.

12. The method of claim 11, further comprising:
forming a second open trench between second layers of the semiconductor;
filling a second gap layer and a bottom portion of the second open trench with the dielectric; and
filling an upper portion of the second open trench with a second conductor.

13. The method of claim 12, wherein:
the conductive material of the open trench forms a local bitline, and
the second conductor of the second open trench forms a conductive element of a capacitor.

14. The method of claim 12, wherein the thinning process:
thins the layers of the semiconductor, and
thins the second layers of the semiconductor.

15. The method of claim 12, wherein a filling process of the dielectric:
fills the gap layer and bottom portion of the open trench, the dielectric being allowed to grow to fill in a portion of the gap layer and the bottom portion of the open trench, and
fills the second gap layer and bottom portion of the second open trench, the dielectric being allowed to grow to fill in a portion of the second gap layer and the bottom portion of the second open trench.

16. The method of claim 11, wherein a filling process of the dielectric is based on area-selective deposition.

17. The method of claim 11, wherein a filling process of the dielectric is based on flowable chemical vapor deposition.

18. The method of claim 11, further comprising:
forming a liner material over exposed surfaces of the open trench, including the thinned layers of the semiconductor, the liner material comprising a non-growth material that inhibits growth of the dielectric.

19. The method of claim 11, wherein forming the layers of the semiconductor comprise removing layers of a second semiconductor interleaved between layers of the semiconductor, the layers of the semiconductor comprising multiple layers of a first thickness and the bottom layer of the semiconductor having a second thickness less than the first thickness.

20. A fabrication device for fabricating memory devices, the fabrication device being configured to:
form an open trench between layers of a semiconductor;
perform a thinning process that includes forming thinned layers of the semiconductor the thinning process and forming a gap layer by removing a bottom layer of the semiconductor;
fill the open trench with a dielectric that covers exposed surfaces of the open trench, including the thinned layers of the semiconductor;
perform a removal process that includes removing an upper portion of the dielectric, the dielectric remaining in the gap layer and a bottom portion of the open trench; and
fill a portion of the open trench above the dielectric with a conductive material.
